(19) United States
(12) Patent Application Publication
(10) Pub. No.: US 2008/0258722 A1
(43) Pub. Date: Oct. 23, 2008

(54) Sensor Arrangement

(75) Inventors: Hans Zon, Waalre (NL); Jaap Ruigrok, Asten (NL); Jan Cornelis Hoeven, Veldhoven (NL); Kim Phan Le, Waalre (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/576,141

(22) PCT Filed: Sep. 21, 2005
(86) PCT No.: PCT/IB05/53110

§ 371 Date: Jan. 29, 2008

(30) Foreign Application Priority Data
Sep. 27, 2004 (EP) 04104681.4
Aug. 26, 2005 (EP) 05107850.9

(51) Int. Cl. G01R 33/025

(52) U.S. Cl. 324/260

(57) ABSTRACT

Consistent with an example embodiment, devices comprise sensor arrangements with field detectors for detecting components of magnetic fields in planes of the field detectors. The sensor arrangements further include movable objects for, in response to tilting movements, changing at least parts of the components of the magnetic fields in the planes of the field detectors so that the sensor arrangements are made less sensitive to in-plane stray fields by providing the field detectors with saturated field-dependent elements. The movable object may comprise a movable field generator for generating the magnetic field, or the movable object and the field generator may be different objects. The magnetic field is such that the field-dependent element is saturated. The field generator is smaller than the field detector, and the movable object is larger than the field detector, to reduce alignment problems. The movable object has a pivoting point close to the field detector.

The invention relates to a device comprising a sensor arrangement, and also relates to a sensor arrangement, and to a sensing method.

Examples of such a device are portable pc's and small handheld electronic devices such as mobile phones, personal digital assistants, digital camera's and global positioning system devices.

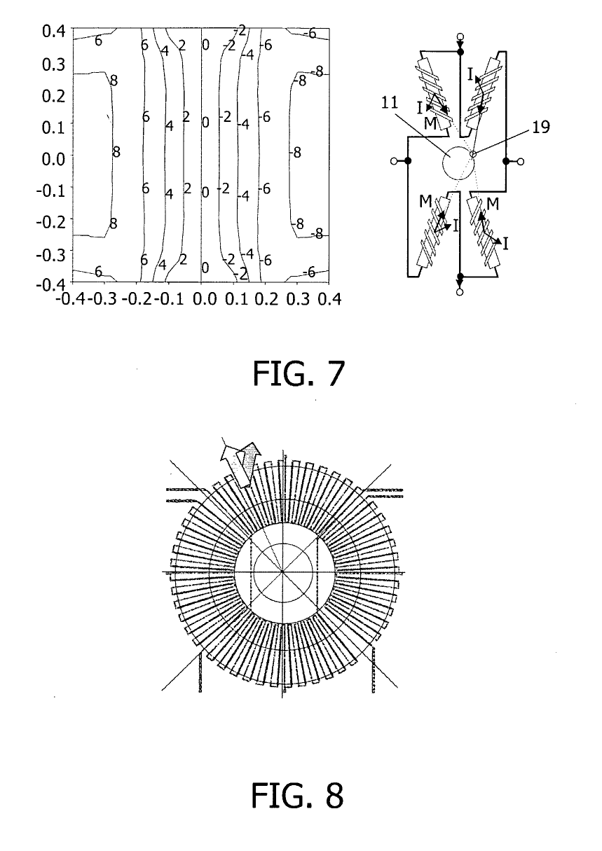

Such a device is known from German patent application DE 43 17 512 A1. FIG. 6 of this document discloses a sensor arrangement with a movable magnet and a field detector. FIG. 7 discloses a sensor arrangement with a fixed magnet located directly under a field detector and with an indicator comprising ferromagnetic material located above the field detector. The field detector is sensitive to in-plane field components only. The sensor arrangements of FIGS. 6 and 7 are extremely sensitive to in-plane stray magnetic fields, which is considered a disadvantage.

It is an object of the invention, inter alia, to provide a device in which the sensor arrangement is less sensitive to in-plane stray magnetic fields.

Furthers objects of the invention are, inter alia, to provide a sensor arrangement which is less sensitive to in-plane stray magnetic fields and a sensing method which is less sensitive to in-plane stray magnetic fields.

The device according to the invention comprises a sensor arrangement. The sensor arrangement comprises a field detector for detecting a component of a magnetic field in a plane of the field detector; and a movable object for, in response to a movement, changing at least a part of the component of the magnetic field in the plane of the field detector. The field detector comprises at least one saturated field-dependent element.

The field detector comprises at least one field-dependent element, which is saturated. Owing to the element being saturated, it is less sensitive to in-plane stray magnetic fields. As a result, the sensor arrangement is less sensitive to in-plane stray magnetic fields. Such a field-dependent element might comprise an anisotropic magneto-resistive material (for example an NiFe-alloy) or a magneto-resistive material (for example a giant or tunnel magneto resistance), without excluding further materials.

An embodiment of the device according to the invention has the movable object being a movable field generator for generating the magnetic field. In this case, the movable object and the generator are one and the same object.

An embodiment of the device according to the invention further comprises a field generator for generating the magnetic field, the movable object comprising a movable field conductor. In this case, the field generator and the movable object are different objects.

An embodiment of the device according to the invention is characterized in that the field generator is or comprises a permanent magnet. Such a permanent magnet does not require a power supply, which is advantageous. Especially for portable and small handheld electronic devices, a low power consumption is of the utmost importance.

An embodiment of the device according to the invention is characterized in that the magnetic field comprises a radial magnetic field in the plane of the field detector. Preferably, the magnetic field comprises a radial magnetic field in the plane of the field detector, and the field detector detects a radial field component in the plane of the field detector.

An embodiment of the device according to the invention is characterized in that the magnetic field is such that the at least one field-dependent element is saturated. The at least one field-dependent element is magnetically saturated by the magnetic field itself.

An embodiment of the device according to the invention is characterized in that the at least one field-dependent element detects a direction of the magnetic field. In this case, the component of the magnetic field comprises a direction.

An embodiment of the device according to the invention is characterized in that the at least one field-dependent element comprises a resistor with a barberpole strip. Such a resistor comprises, e.g., an anisotropic magneto-resistive strip, on which one or more barberpole strips (metallic strips) have been mounted. These barberpole strips are highly electrically conducting and change a direction of the current in the anisotropic magneto-resistive strip. The anisotropic magneto-resistive strip has a resistance value which depends on the angle between the direction of the magnetization in the material and the direction of the current. The main function of the barberpole strips is to linearize the response curve of the element.

An embodiment of the device according to the invention is characterized in that the field generator comprises a dimension in a plane parallel to the plane of the field detector, the dimension being smaller than a dimension of the field detector in the plane of the field detector. The field generator can now be made smaller than the field detector, which is a great advantage;

An embodiment of the device according to the invention is characterized in that the movable object has a dimension in a plane parallel to the plane of the field detector, the dimension being is larger than a dimension of the field detector in the plane of the field detector. This reduces the alignment problems of the indicator present in the known sensor arrangements.

An embodiment of the device according to the invention is characterized in that the movable object has a tilted plane closest to the field detector, of which a tilt angle is dependent on the movement of the movable object. The tilting of the movable object instead of the shifting in the known devices has proven to be advantageous.

An embodiment of the device according to the invention is characterized in that the movable object has a pivoting point located between a center of the movable object and an end of the movable object located closest to the field detector. This is done, for example, with the intention to change the orientation of the bottom plane of the movable object with respect to the field generator. Such a pivoting point might preferably correspond with, for example, the end of the movable object located closest to the field detector. In case of the pivoting point coinciding with a position between the center and the end of the movable object, an angle as well as a lateral distance between the movable object and the field detector are changed when the movable object is moved. By shifting the pivoting point to the end of the movable object located closest to the field detector, this changing lateral distance is reduced or even avoided.

An embodiment of the device according to the invention is characterized in that the field detector is located between the field generator and the movable object. This configuration has proven to be very efficient, and allows the movable object to be most simple and robust.

An embodiment of the device according to the invention is characterized by the field detector comprising a first Wheatstone bridge for detecting a first dimension of the component and a second Wheatstone bridge for detecting a second dimension of the component. These Wheatstone bridges preferably each comprise one or more field-dependent elements. For a maximum sensitivity, all elements of each Wheatstone bridge are preferably field-dependent elements.

An embodiment of the device according to the invention is characterized by the field detector comprising a Wheatstone bridge. This Wheatstone bridge comprises field-dependent elements set under an angle between substantially 0 and substantially 45 degrees with respect to an X-axis and an Y-axis. This is done to improve an independence between X-movements and Y movements.

An embodiment of the device according to the invention is characterized by the field-dependent elements being set under an angle between substantially 20 and substantially 30 degrees with respect to the X-axis and the Y-axis. This is done to get an optimal independence between X-movements and Y movements.

An embodiment of the device according to the invention is characterized by the field detector comprising a meander system. This is done to increase the resistance value of the field detector to reduce the power consumption.

An embodiment of the device according to the invention is characterized by the meander system comprising eight meanders, each meander covering a segment of a circle. Such a meander system with eight meanders provides an optimal independence between X-movements and Y movements. Each meander then covers about 45 degrees of a circle, so the average of a segment corresponds with 22.5 degrees, which is again between 20 and 30 degrees.

Embodiments of the sensor arrangement according to the invention and of the method according to the invention correspond with the embodiments of the device according to the invention.

The invention is based upon an insight, inter alia, that field detectors are sensitive to in-plane field components only, which results in an extreme sensitivity to in-plane stray magnetic fields. The invention is based upon a basic idea, inter alia, that to get a reduced sensitivity to such in-plane stray fields, the field detector should comprise at least one saturated field-dependent element.

The invention solves the problem, inter alia, by providing a device wherein the sensor arrangement is less sensitive to in-plane stray fields, and is advantageous, inter alia, in that any in-plane stray fields will disturb the sensor arrangement to a smaller extent.

The device of the invention as specified above can be a peripheral, e.g., a pointing device, to a data processing system, or can be a data processing system, e.g., a cell phone, a PDA, etc., that itself accommodates the pointing device.

These and other aspects of the invention will be apparent from and elucidated with reference to the embodiments(s) described hereinafter.

The invention is further explained, by way of example and with reference to the accompanying drawing wherein:

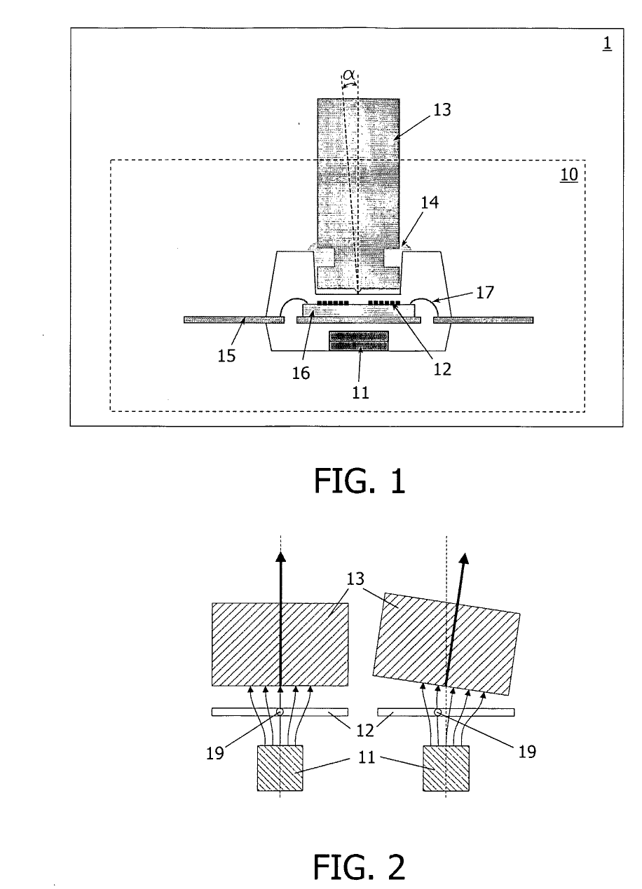

FIG. 1 is a diagram of a device in the invention comprising a sensor arrangement according to the invention shown in cross section;

FIG. 2 is a diagram illustrating a performance of the sensor arrangement according to the invention;

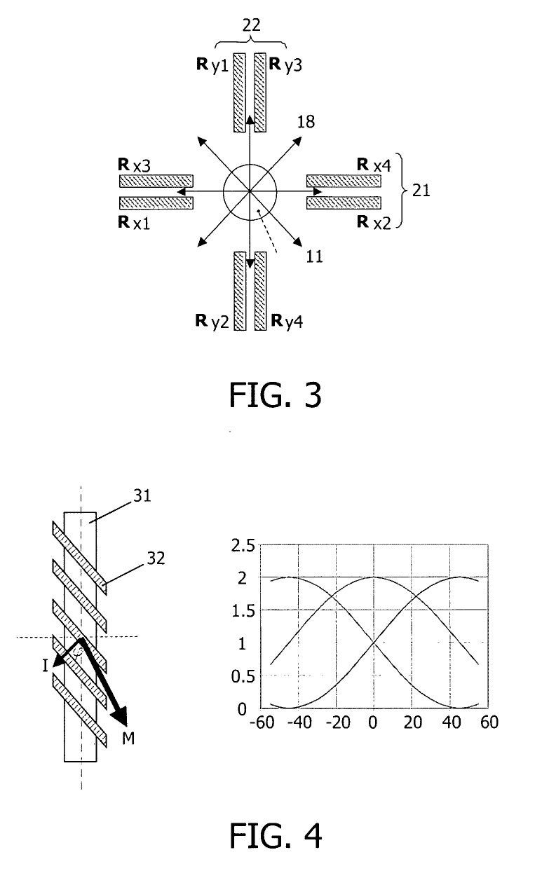

FIG. 3 shows two Wheatstone bridges for detecting radial field components in the X-direction and the Y-direction, each comprising field-dependent elements;

FIG. 4 shows a field-dependent element comprising an anisotropic magneto-resistive strip on which barberpole strips have been mounted, and a response characteristic;

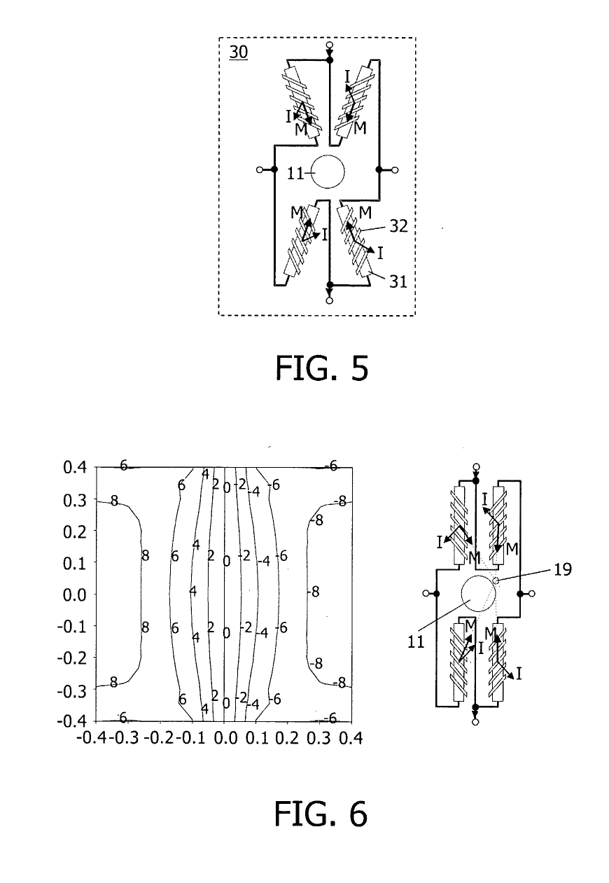

FIG. 5 shows a Wheatstone bridge comprising anisotropic magneto-resistive strips on which barberpole strips have been mounted;

FIG. 6 shows a first configuration of a Wheatstone bridge comprising anisotropic magneto-resistive strips on which barberpole strips have been mounted, and an output voltage as a function of a position of a center of a radial field component;

FIG. 7 shows a second configuration of a Wheatstone bridge comprising anisotropic magneto-resistive strips on which barberpole strips have been mounted which shows an improved independency between X movements and Y movements, and an output voltage as a function of a position of a center of a radial field component; and

FIG. 8 shows a sensor arrangement with parallel anisotropic magneto-resistive strips to increase the total resistance and having improved characteristics.

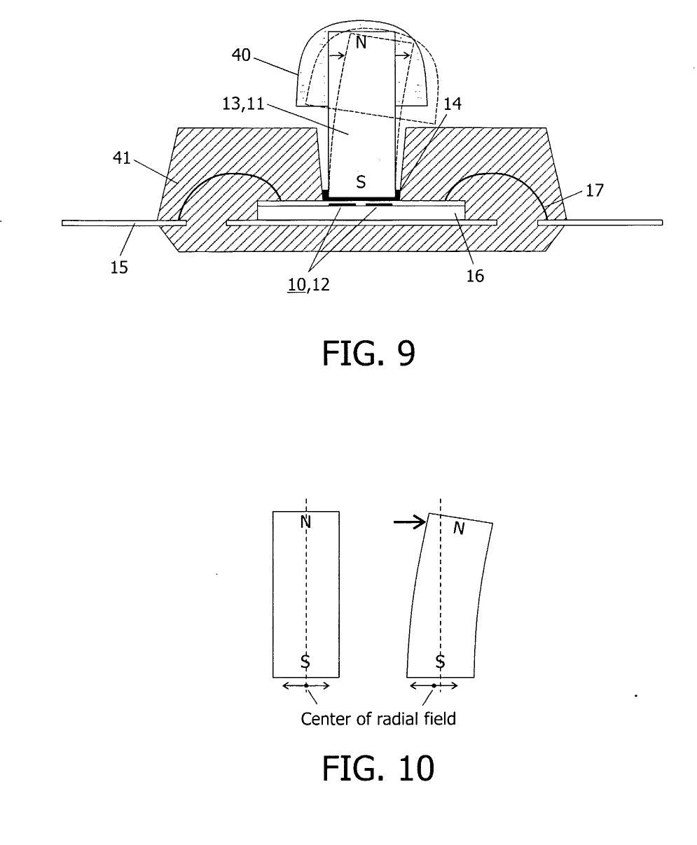

FIG. 9 shows an embodiment of the device according to the invention wherein the movable object comprises a flexible magnetic material.

FIG. 10 illustrates that the center of the radial field is displaced when the movable object comprising flexible material is bent.

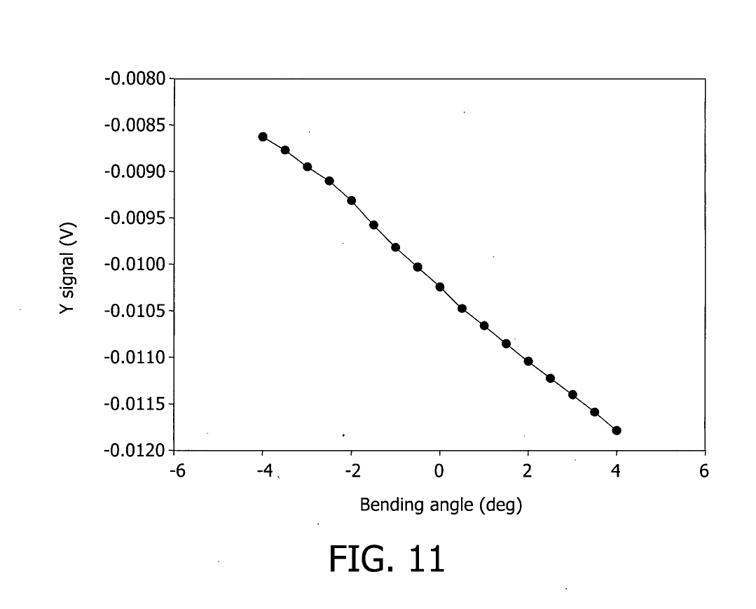

FIG. 11 shows experimental data of the output signal in the bridge Y (which lies along the Y-direction) as a function of bending angle in the X-direction.

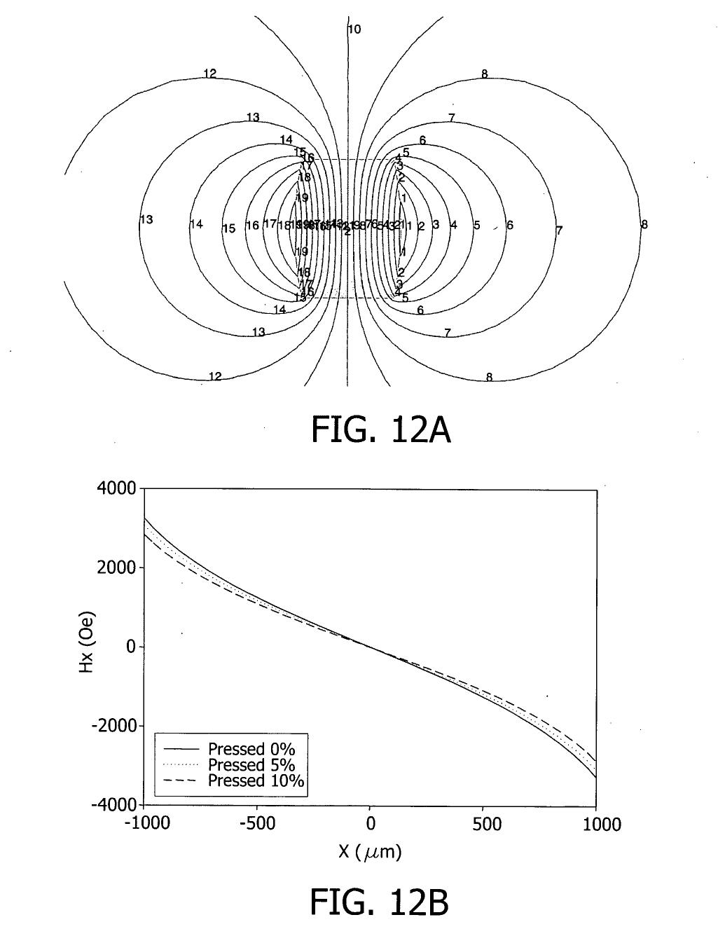

FIG. 12 A shows a simulation of a flexible joystick being pressed in the vertical direction.

FIG. 12B illustrates that a change in the in-plane component of magnetic field (Hx) of about 6% and 13% at the sensor location is observed when the stick is compressed by 5% and 10% in the vertical direction, respectively.

In portable PCs or small handheld electronic devices such as mobile telephones, PDAs, digital cameras or GPS devices, often an analog pointing device functionality is required. Various designs for analog pointing devices already exist in the market such as piezo-electric or optical pointing devices. Piezo-electric pointing devices require a complex micro-controller to compensate for the drift in the sensor. Optical pointing devices are available but have relatively high power consumption. In this invention, a magnetic pointing device is proposed that is simple in construction, requires relatively simple electronics, has low power consumption and can be fully integrated within a semiconductor chip package.

The device 1 according to the invention shown in FIG. 1 comprises a sensor arrangement 10 according to the invention. The sensor arrangement 10 comprises a field generator 11 for generating a field, such as for example a magnet for generating a magnetic field. The sensor arrangement 10 further comprises a field detector 12 for detecting a component 18 (as shown in FIG. 3) of the magnetic field, and a movable object 13 such as a movable field conductor such as a joy stick for, in response to a movement, changing at least a part of the component 18. This changing for example comprises the shifting of a center 19 (as shown in FIG. 2). The component 18 for example comprises a direction.

The field generator 11 such as a permanent magnet and the movable object 13 such as a ferrite stick are for example integrated in a chip plus a package. The package is modified in such a way that the movable object 13 can be mounted in a blind hole in the package with flexible glue 14, an O-ring or any other mechanical spring. In this way the chip in the package remains protected against moist, dirt, scratches as if it were a normal package. In addition normal reflow soldering processes remain possible. In this embodiment the chip with the field detector 12 is placed close to a signal-processing chip (with for example a micro controller) in one package 41. The short distance between the chips reduces the influence of noise. Another advantage of using a micro-controller is that it can be programmed for the type of I/O signal, filtering, a threshold, amplification factors or even the function of some of the package leads. The field detector 12 is mounted on a substrate 16, which is coupled via wirebonds 17 to a leadframe 15.

The sensor arrangement 10 shown in FIG. 2 with the movable object 13 comprises a pivoting point located between a center of the movable object 13 and an end of the movable object 13 located closest to the field detector 12. Preferably, this pivoting point substantially coincides with this end of the movable object 13 located closest to the field detector 12. By pivoting the movable object 13, the center 19 of the component 18 (as shown in FIG. 3) is shifted, which is detected by the field detector 12. Such a field detector 12 comprises, e.g., two Wheatstone bridges shown in FIG. 3.

The Wheatstone bridges 21 and 22 in FIG. 3 detect components 18 in the X-direction and the Y-direction. The X-direction and the Y-direction are, for example, substantially perpendicular to each other. A first one of the Wheatstone bridges 21 and 22 detects a first part of the component 18, and a second one of the Wheatstone bridges 21 and 22 detects a second part of the component 18. Each of the bridges 21 and 22 comprises one or -more field-dependent elements such as magnetic field-dependent resistors, which are shown in greater detail in FIG. 4. Their resistance values are aimed to be in the kilo Ohm range in order to limit power consumption. Such a resistance value is altered if a magnetic field is applied to the resistor due to the use of so-called anisotropic magneto-resistive materials (e.g., an NiFe-alloy). Typically the resistance value change of such a resistor under the influence of the magnetic field is about 2% in practical circumstances. Other magneto-resistive materials exist such as giant magneto resistive and tunnel magneto resistive materials, which give a much larger change in the resistance value. Basically the field detector 12 could also be made with these materials. However the great advantage of using anisotropic magneto-resistive materials lies in the simplicity of the material itself (a single layer of an NiFe-alloy compared to a complicated multi-layer stack in case of the other materials) and in the ease with which the response characteristic (e.g., resistance value versus magnetic field) can be altered. In the case of other materials the response characteristic has to be manipulated by means of setting and fixing magnetization directions in the stack, whereas in the case of anisotropic magneto-resistive materials the response characteristic can be set merely by forcing the electrical current through the field-dependent elements in a required direction. This can be done by using the proper layout.

In an X-Y field, detector-independent signals for the movement in the X-direction and the Y-direction have to be generated. For each direction (X, Y) a Wheatstone bridge configuration is used consisting of four resistors made of anisotropic magneto-resistive materials. These two Wheatstone bridges 21 and 22 are placed in a static radial magnetic field. The field is generated by a permanent magnet or a magnetized piece of material such as ferrite which in size is small compared to the total layout of the sensor. Another possibility is to generate the magnetic field by means of a coil or single conductor carrying an electrical current. In the proposed configuration the anisotropic magneto-resistive materials are deposited and patterned on an Si/SiO₂ substrate. The permanent magnet is positioned beneath the Si/SiO₂ substrate. The two Wheatstone bridges 21 and 22 for the X- and Y-direction are visible where each bridge consists of four resistors numbered Rₓ₁ to Rₓ₄ and R_{y1} to R_{y}. Both bridges are positioned under substantially 90 degrees with respect to each other. Bridge Y, which lies along the Y-direction, is sensitive to a change in magnetic field in the X-direction (e.g., caused by the movable field conductor which is positioned above the field detector), whereas bridge X is sensitive to a change in magnetic field in the Y-direction.

At the center of the four resistors of a Wheatstone bridge 21,22 the permanent magnet is placed. The size of the permanent magnet is small compared to the total dimensions of the field detector 12. Under these circumstances the permanent magnet generates a radially oriented magnetic field in the plane of the field detector 12. The center of the pattern coincides with the center of the four resistors. When the resistors are also placed in a radial configuration, the in-plane magnetic field lines will be parallel to the length directions of the resistors. The described configuration is actually the magnetic field configuration of the field detector 12 in rest, i.e., the magnetic field lines are not disturbed, by the presence of, e.g., the movable field conductor. The strength of the magnetic field is preferably large enough to fully saturate the resistors, which means that the magnetization direction in the resistor strips is parallel to the radial field lines. Such a strong field has the advantage that the field detector 12 becomes more insensitive to the influence of stray-fields present around the sensor arrangement 10 (e.g., due to currents flowing in the neighborhood of the sensor arrangement).

The field-dependent element 31 shown in FIG. 4 comprises a resistor in the form of an anisotropic magneto-resistive strip or AMR strip on which barberpole strips 32 have been mounted. In FIG. 4, a response characteristic of the field-dependent element 31 is shown (AMR ratio in % versus an angle of magnetization for three current angles −45, 0 and +45 degrees). In an anisotropic magneto-resistive material resistor the resistance value is determined by the angle between the magnetization in the magnetic layer and the current which flows in this magnetic layer. The resistance can be expressed by the equation R=R₀+ΔRcos²φ where R₀ is the base resistance value of the resistor, ΔR is the maximum change in resistance possible and φ is the angle between the in-plane magnetization M and the in-plane current I. The resistor is not sensitive to magnetic fields perpendicular to the plane. The direction of the current is set by means of the electrical layout of the circuit. For these field detectors 12 a barberpole construction is often used to set the direction of the current. Such a barberpole construction consists of thick metallic stripes 32 deposited on top of the AMR strip. Because the barberpole strips 32 are electrically highly conductive, the current will mainly flow perpendicular between the barberpole strips 32. Therefore the direction of the current can be set by choosing the right angle of the barberpole strips 32 with respect to the length direction of the AMR strip and is fully determined by the lithographical design of this configuration.

Without an external magnetic field, the magnetization direction in the AMR strip is determined by the shape of the AMR strip (shape anisotropy) and the crystalline anisotropy axis of the NiFe-alloy itself. The direction of the crystalline anisotropy axis can be set by depositing the NiFe-alloy in a magnetic field. Normally the direction of the crystalline anisotropy is chosen parallel to the length direction of the AMR strip. However, sometimes this is not possible in case the AMR strips have for example two (or more) directions. In case of two strip directions the crystalline anisotropy axis can be set under an angle of substantially 45 degrees with respect to the AMR strips to create some form of symmetry but if more directions are present this is hardly possible.

If the width of the AMR strips is reduced compared to the length, the shape anisotropy starts to dominate and the magnetization will be forced parallel to the length direction of the AMR strips in the absence of an external magnetic field. If also barberpole strips 32 are absent, the current through the magnetic layer is parallel to the magnetization and the AMR strip has a high resistance value equal to R₀+ΔR ((φ=0). A small change in the magnetization direction hardly influences the resistance due to the shape of the cos²φ-function. Actually the sensitivity around zero field is zero. This can be improved by the use of the barberpole strips 32 that change the direction of the current. Normally the barberpole strips 32 are set under an angle of (+or −) 45 degrees with respect to the length direction of the AMR strip. Therefore the angle between the current flowing through the field detector 12 and the magnetization will also be (+or −) 45 degrees. If the direction of the magnetization with respect to the axis of the AMR strip is changed due to a change in the magnetic field, the angle between the current and the magnetization changes and accordingly the resistance value of the AMR strip. In FIG. 4 the response characteristic of the AMR strip is shown as a function of the angle of the magnetization with respect to the length axis of the AMR strip for three different directions of the current. For current directions of (+or −) 45 degrees the response characteristic shows a linear behavior around 0 degrees. The direction of the barberpole strips 32 determines the shape of the response characteristic barberpole strips 32 set under −45 degrees will show a mirrored response characteristic. When constructing a complete Wheatstone bridge, the directions of the barberpole strips 32 on the various resistors should be such that the Wheatstone bridge shows a maximum sensitivity. FIG. 5 shows such a configuration.

Referring to FIGS. 5-7, when the movable object 13 is in its rest position, the magnetizations in the resistors show a pattern according to the in-plane radial magnetic field lines of the permanent magnet. Therefore the magnetizations are either pointing to the center of the permanent magnet or pointing to the outward side of the pointing device sensor. For all AMR strips the angle between the currents and the magnetizations is (+or −) 45 degrees and all response characteristics are in their central point. By means of a magnetically conductive stick placed above the center of the permanent magnet, the radial magnetic field can be influenced. In the proposed sensor arrangement 10 the field detector 12 is placed between the permanent magnet and the movable field conductor or pointing device. The distance between the permanent magnet and the field detector 12 and the distance between the field detector 12 and the pointing device can be optimized. The actual function of the stick is to change the position of the center 19 of the radial field while maintaining the strength of the magnetic field. FIG. 2 shows the function of the magnetically conductive stick. This can be done for example by changing the angular position of the stick. The design of the stick is such that the bottom part does not change its lateral position but only the angle with respect to the field detector surface.

The net result of the change in the angular position of the stick is the change in position of the center 19 of the radial magnetic field as indicated by the small circle in FIG. 2. This change alters the directions of all magnetic moments in the AMR strips thereby changing the resistance values and thus the output signals of the Wheatstone bridge. This is shown in FIG. 6. FIG. 6 also shows the result of a calculation of the output signal of the Wheatstone bridge as a function of the position of the center of the radial field (output ratio in mV/V versus position in mm). In this calculation it is assumed that the various magnetizations are in the direction of the radial field at the position of the field detector 12. This assumption is correct if large magnetic fields are used. As an example Wheatstone bridge Y is considered which is sensitive to a position change in the X-direction. Although it is desired that the output is completely independent of the movement of the stick in the Y-direction, it can be seen that it still is slightly influenced by such a movement. However this can be improved by choosing a different configuration of the AMR strips as is shown in FIG. 7. In this case the AMR strips are set under an angle somewhere between substantially 0 and substantially 45 degrees with respect to the X- and Y-axis, preferably between substantially 20 and substantially 30 degrees with respect to the X- and Y-axis. The corresponding output characteristic is also shown in FIG. 7 (output ratio in mV/V versus position in mm). It is clear that an improvement with respect to the original output characteristic has been obtained. Dependent on the required resistance of the Wheatstone bridge, the total resistance of a bridge element 31 can be increased by placing several line elements in series. In that case all the line segments are positioned in such a way that the axes of the line segments pass through the center of the permanent magnet, i.e., all line segments show a radial pattern.

FIG. 8 shows a sensor arrangement with anisotropic magneto-resistive strips to increase the total resistance and having improved characteristics. This field detector comprises a meander system. This increases the resistance value of the field detector and reduces power consumption. Preferably, the meander system comprises eight meanders, each meander covering a segment of a circle. Such a meander system with eight meanders provides an optimal independence between X-movements and Y movements. Each meander then covers about 45 degrees of a circle, so the average of a segment corresponds with about 22.5 degrees, which is again between 20 and 30 degrees.

The sensor arrangement 10 has a more efficient configuration. This configuration results in and/or comes from a smaller field generator 11, a more efficient use of the field by the field detector 12, a movement of the movable object 13 being better detectable, a reduced sensitivity to disturbing fields, lower costs, more linearity, etc.

Alternatively, the movable object 13 may comprise a field generator, without departing from the scope of this invention.

FIG. 9 shows an embodiment of the device according to the invention wherein the movable object 13 comprises a magnetic field generator 11 in the form of a flexible magnetic material. The flexible magnetic material contains a permanent magnet powder or magnetic particles (such as NdFeB, Ba ferrite, SmCo) suspended in a matrix of an elastic material such as an elastomer rubber. Examples of such an elastomer rubber are polydimethylsiloxane (PDMS), polyurethanes (PU), room temperature vulcanizing (RTV) elastomer, buthyl rubber, etc. The material possesses a remanent magnetic moment like a permanent magnet and moreover it can be deformed elastically. The flexible permanent magnet material preferably behaves elastically with small hysteresis and its remanent magnetic moment is sufficient to saturate the AMR sensors.

The flexible magnet joystick (i.e. the movable object 13) made of the flexible permanent magnetic material is glued firmly at one end onto the top surface of the sensor substrate (see FIG. 9). The shape of the joystick can for example be a cylinder or prismoid (such as rectangular prism).

The flexible magnet joystick is magnetized along the length of the stick 11,13. A button-shaped cap 40 may be mounted on top of the joystick for decoration and protection. In the absence of an external force, the stick is straight and stands up right. The center of the radial field in this case coincides with the center of the sensor structure, thus resulting in no signals on the outputs (FIG. 10, left). When the joystick is pushed by the user's finger, it slightly bends (e.g. a few degrees) to a certain direction (FIG. 10, right). This will displace the center of the radial field in the opposite direction and similarly to FIG. 2 and FIG. 3, this displacement will result in signal changes in X and Y bridges outputs.

The operation of the flexible joystick is illustrated in the following example of a finite element simulation. A flexible joystick having a rectangular prism shape of 2 mm×2 mm and a length of 8 mm is bent 5 degrees in the X-direction. The in-plane component of the magnetic field (Hx) as detected by the magnetic field detector 12 along a line parallel-to the X-direction 50 μm under the bottom of the stick is calculated. In this case the center of the radial field is displaced 31 μm in the X-direction from the center of bottom surface of the stick. This displacement results in about 1.5 mV change in the output signal of bridge Y, which lies along the Y-direction.

In FIG. 11 an experiment result is given where the change in output signal of bridge Y is plotted versus the bending angle of the joystick (in X direction). The sensitivity is 0.42 mV/degree for the bridge input voltage of 3V.

If the dimensions of the joystick are scaled up, the displacement of the center of the radial field is also enlarged proportionally, with the same amount of bending angle. Therefore it would be advantageous to maximize the size of the joystick. The size of the joystick is limited by the dimensions and construction of the sensor and package as a whole.

Simulations show that with the same diameter and same bending angle, the shorter the stick, the larger the displacement can be obtained. This is because with the same bending angle, the curvature of the shorter stick is larger than that of a longer stick.

The flexible joystick may also be used for operation in the vertical direction along the z-axis perpendicular to the X-Y plane. The bulk modulus of the material of the joystick is so large that when pressed vertically, the volume of the stick remains unchanged. This means when pressed, the stick is reduced in length and expanded in lateral directions. In a 2D simulation model (FIG. 12A), a joystick measuring 2.5 mm in diameter and 4.5 mm in length is compressed 5 and 10% in the vertical z-direction (length). In-plane field component (Hx) has been calculated for these cases (FIG. 12B), which reveals that when pressed 5% and 10%, a change of about 6% and 13% in magnetic field, respectively, can be obtained at the location of the sensor. This change results in detectable signal change in the output signals of the sensors in the X-Y plane, using the common mode of the Wheatstone bridge.

For example one or more relative sizes and/or one or more field detectors and/or one or more configurations may become the subject of one or more divisional applications without being limited to the saturated field-dependent elements.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A device with a sensor arrangement comprising:
a field detector for detecting a component of a magnetic field in a plane of the field detector and
a movable object for, in response to a movement, changing at least a part of the component of the magnetic field in the plane of the field detector; and wherein the field detector comprises at least one saturated field-dependent element.

2. The device of claim 1, wherein the movable object comprises a movable field generator for generating the magnetic field.

3. The device of claim 1, further comprising a field generator for generating the magnetic field and wherein the movable object comprises a movable field conductor.

4. The device of claim 3, wherein the field generator comprises a permanent magnet.

5. The device of claim 1, wherein the magnetic field comprises a radial magnetic field in the plane of the field detector.

6. The device of claim 1, wherein the magnetic field is such that the at least one field-dependent element is saturated.

7. The device of claim 1, wherein the at least one field-dependent element (31) is operative to detect a direction of the magnetic field.

8. The device of claim 1, wherein the at least one field-dependent element comprises a resistor with a barber pole strip.

9. The device of claim 3, wherein the field generator has a first dimension in a plane parallel to the plane of the field detector, the first dimension being smaller than a second dimension of the field detector in the plane of the field detector.

10. The device (1) of claim 1, wherein the movable object has a first dimension in a plane parallel to the plane of the field detector, the first dimension being larger than a second dimension of the field detector in the plane of the field detector.

11. The device of claim 1, wherein the movable object has a tilted plane closest to the field detector, of which a tilt angle is dependent on the movement of the movable object.

12. The device of claim 1, wherein the movable object comprises a pivoting point located between a center of the movable object and an end of the movable object located closest to the field detector.

13. The device (1) of claim 3, wherein the field detector is located between the field generator and the movable object.

14. The device (1) of claim 1, wherein the field detector comprises a first Wheatstone bridge for detecting a first part of the component and a second Wheatstone bridge for detecting a second part of the component.

15. The device (1) of claim 1, wherein the field detector comprises a Wheatstone bridge with field-dependent elements set under an angle between substantially 0 and substantially 45 degrees with respect to an X-axis and a Y-axis.

16. The device of claim 12, wherein the field-dependent elements are set under an angle between substantially 20 degrees and substantially 30 degrees with respect to an X-axis and a Y-axis.

17. The device of claim 1, wherein the field detector comprises a meander system.

18. The device of claim 17, wherein the meander system comprises eight meanders, each of the meanders covering a segment of a circle.

19. The device of claim 1, wherein the movable object comprises a flexible magnetic material.

20. The device of claim 19, wherein the flexible magnetic material comprises a magnetic powder or magnetic particles suspended in a flexible material.

21. A sensor arrangement comprising a field detector for detecting a component of a magnetic field in a plane of the field detector and comprising a movable object for, in response to a movement, changing at least a part of the component of the magnetic field in the plane of the field detector, wherein the field detector comprises at least one saturated field-dependent element.
